(19) United States
(12) Patent Application Publication
(10) Pub. No.: US 2023/0165074 A1
(43) Pub. Date: May 25, 2023

(54) Organic Light-Emitting Display Device

(71) Applicant: LG Display Co., Ltd., Seoul (KR)

(72) Inventors: Dong Chae Shin, Paju-si (KR); Sun Young Choi, Paju-si (KR); Mi Jin Jeong, Paju-si (KR)

(21) Appl. No.: 17/900,694

(22) Filed: Aug. 31, 2022

(30) Foreign Application Priority Data
Nov. 25, 2021 (KR) 10-2021-0164357

(51) Int. Cl. H01L 27/32

(52) U.S. Cl. CPC H01L 27/3272

(57) ABSTRACT

An organic light-emitting display device is disclosed. The organic light-emitting display device comprising: a substrate comprising a first area and a second area; a driving thin-film transistor disposed in the second area, the driving thin-film transistor comprising a first oxide semiconductor pattern; and at least one switching thin-film transistor disposed in the second area, wherein the switching thin-film transistor comprises a first switching thin-film transistor comprising a second oxide semiconductor pattern, wherein the driving thin-film transistor comprises a first light-blocking pattern disposed below the first oxide semiconductor pattern so as to overlap the first oxide semiconductor pattern, and wherein a vertical distance between the first light-blocking pattern and the first oxide semiconductor pattern is shorter than a vertical distance between the first light-blocking pattern and the second oxide semiconductor pattern.

### CROSS-REFERENCE TO RELATED APPLICATION

This application claims the benefit of Republic of Korea Patent Application No. 10-2021-0164357, filed on Nov. 25, 2021, which is hereby incorporated by reference in its entirety.

### BACKGROUND

### Field of Technology

The present disclosure relates to an organic light-emitting display device, and more particularly to an organic light-emitting display device that includes hybrid-type thin-film transistors, in which different types of semiconductor materials are used to form a plurality of thin-film transistors constituting a pixel circuit portion of a sub-pixel and a plurality of thin-film transistors constituting a gate-in-panel (GIP) circuit portion.

### Discussion of the Related Art

Unlike a liquid crystal display device using a backlight, an organic light-emitting display device uses a self-luminous light-emitting element, and thus is thin and exhibits a high image quality. Thus, an organic light-emitting display device is the focus of much attention in the display field.

In particular, since it is possible to form a light-emitting element on a flexible substrate, an organic light-emitting display device enables a screen to be created in various forms, such as a bendable screen or a foldable screen. In addition, due to the small thickness thereof, an organic light-emitting display device is suitable for small electronic products, such as smart watches.

Further, in order to be applied to a display device that frequently displays a still image, such as a smart watch, a light-emitting display device including a new type of pixel circuit portion capable of preventing generation of leakage current when displaying a still image is required.

A thin-film transistor that uses an oxide semiconductor as an active layer in order to obtain an improved leakage-current-blocking effect has been proposed.

### SUMMARY

However, in a display device that uses hybrid-type thin-film transistors, different types of semiconductor layers (e.g., a polycrystalline semiconductor layer and an oxide semiconductor layer) are used. Thus, a process of forming the polycrystalline semiconductor layer and a process of forming the oxide semiconductor layer are performed separately from each other, thus complicating the manufacturing process. Further, a polycrystalline semiconductor layer and an oxide semiconductor layer have different characteristics with respect to chemical gases, thus complicating the manufacturing process.

In particular, compared to an oxide semiconductor layer, a polycrystalline semiconductor layer is characterized in that carriers, such as electrons or holes, move at a high speed, and is thus suitable for a driving thin-film transistor that is required to be capable of high-speed operation. Accordingly, a polycrystalline semiconductor layer is typically used to form a driving thin-film transistor.

However, a driving thin-film transistor that uses a polycrystalline semiconductor layer operates at a relatively high speed, but is disadvantageous from the aspect of expression of low grayscale values due to a high current fluctuation rate resulting from current stress. Therefore, it is an object of the present disclosure to form a driving thin-film transistor using an oxide semiconductor and to provide a pixel circuit portion in which a current fluctuation rate resulting from current stress is low and an s-factor value is large.

In order to accomplish the above and other objects, an organic light-emitting display device according to the present disclosure includes a substrate including a first area and a second area, a driving thin-film transistor disposed in the second area and including a first oxide semiconductor pattern, and at least one switching thin-film transistor disposed in the second area. The switching thin-film transistor includes a first switching thin-film transistor including a second oxide semiconductor pattern. The driving thin-film transistor includes a first light-blocking pattern disposed below the first oxide semiconductor pattern so as to overlap the first oxide semiconductor pattern. A vertical distance between the first light-blocking pattern and the first oxide semiconductor pattern is shorter than a vertical distance between the first light-blocking pattern and the second oxide semiconductor pattern.

In addition, an inorganic film including silicon nitride (SiNx) may be interposed between the first light-blocking pattern and the first oxide semiconductor pattern.

The inorganic film including the silicon nitride may have a shape of an island surrounding the first light-blocking pattern.

The inorganic film including the silicon nitride may be formed on the entire surface of the substrate so as to cover the first light-blocking pattern.

At least one insulating layer may be interposed between the first light-blocking pattern and the first oxide semiconductor pattern, and insulating layers may be interposed between the first light-blocking pattern and the second oxide semiconductor pattern. The number of the insulating layers interposed between the first light-blocking pattern and the second oxide semiconductor pattern may be greater than the number of the at least one insulating layer interposed between the first light-blocking pattern and the first oxide semiconductor pattern.

The first oxide semiconductor pattern and the second oxide semiconductor pattern may be disposed on different layers.

In addition, the organic light-emitting display device according to the present disclosure may further include a lower buffer layer formed on the substrate and an upper buffer layer disposed between the lower buffer layer and the first oxide semiconductor pattern. The driving thin-film transistor may include a second gate electrode overlapping the first oxide semiconductor pattern disposed on the upper buffer layer, with a second gate insulating layer and a third gate insulating layer interposed therebetween, and a second source electrode and a second drain electrode disposed on the second gate electrode and connected to the first oxide semiconductor pattern. The first switching thin-film transistor may include a third gate electrode overlapping the second oxide semiconductor pattern disposed on the second gate insulating layer, with the third gate insulating layer interposed therebetween, and a third source electrode and a third drain electrode disposed on the third gate electrode and connected to the second oxide semiconductor pattern.

In addition, the organic light-emitting display device according to the present disclosure may further include a second light-blocking pattern disposed below the second oxide semiconductor pattern.

The first light-blocking pattern may be connected to the second source electrode.

The second light-blocking pattern may be connected to the third gate electrode.

The substrate may include a display area and a non-display area disposed adjacent to the display area. The first area may be disposed in at least one of the non-display area and the display area, and the second area may be disposed in the display area. A first thin-film transistor including a first polycrystalline semiconductor pattern may be disposed in the first area.

In addition, a second switching thin-film transistor including a third oxide semiconductor pattern may be disposed in the non-display area.

A parasitic capacitance (C_{act}) generated in the first oxide semiconductor pattern may be connected in parallel to a parasitic capacitance (C_{buf}) generated between the first oxide semiconductor pattern and the first light-blocking pattern, and may be connected in series to a parasitic capacitance (C_{gi}) generated between the second gate electrode and the first oxide semiconductor pattern.

Each of the second gate electrode and the third gate electrode may include a plurality of conductive layers, and at least one of the plurality of conductive layers may be a metal layer including titanium.

In addition, the organic light-emitting display device according to the present disclosure may further include a storage capacitor including a first storage capacitor electrode, disposed on the same layer as the second light-blocking pattern, and a second storage capacitor electrode, facing the first storage capacitor electrode, with a first interlayer insulating layer interposed therebetween.

The second storage capacitor electrode may be disposed on the same layer as the first light-blocking pattern.

A does of ions injected into the first oxide semiconductor pattern may be smaller than a dose of ions injected into the second oxide semiconductor pattern.

### BRIEF DESCRIPTION OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure. In the drawings:

FIG. 1 is a schematic view of a display device according to an embodiment of the present disclosure;

FIG. 2 is a circuit diagram showing a pixel circuit for driving one pixel in the display device according to the embodiment of the present disclosure;

FIG. 3 is a cross-sectional view of one thin-film transistor disposed in a non-display area, and a pixel circuit portion and a light-emitting element portion disposed in a pixel area, according to the embodiment of the present disclosure;

FIG. 4A is a cross-sectional view of a driving thin-film transistor according to the embodiment of the present disclosure;

FIG. 4B is a circuit diagram showing the connection relationships between parasitic capacitances generated in the driving thin-film transistor according to the present disclosure;

FIG. 5 is a cross-sectional view of one thin-film transistor disposed in a non-display area, and a pixel circuit portion and a light-emitting element portion disposed in a pixel area, according to another embodiment of the present disclosure;

FIG. 6 is a cross-sectional view of one thin-film transistor and a switching thin-film transistor disposed in a non-display area, and a pixel circuit portion and a light-emitting element portion disposed in a pixel area according to another embodiment of the present disclosure; and

FIG. 7 is a cross-sectional view of a driving thin-film transistor according to another embodiment of the present disclosure.

### DETAILED DESCRIPTION

Advantages and features of the present disclosure and methods for achieving them will be made clear from embodiments described below in detail with reference to the accompanying drawings. The present disclosure may, however, be embodied in many different forms, and should not be construed as being limited to the embodiments set forth herein. Rather, these embodiments are provided so that this disclosure will be thorough and complete, and will fully convey the scope of the present disclosure to those skilled in the art.

In the drawings for explaining the exemplary embodiments of the present disclosure, for example, the illustrated shape, size, ratio, angle, and number are given by way of example, and thus, are not limited to the disclosure of the present disclosure. Throughout the present specification, the same reference numerals designate the same constituent elements. In addition, in the following description of the present disclosure, a detailed description of known functions and configurations incorporated herein will be omitted when it may make the subject matter of the present disclosure rather unclear.

The terms “comprises,” “includes,” and/or “has”, used in this specification, do not preclude the presence or addition of other elements unless used along with the term “only”. The singular forms are intended to include the plural forms as well, unless the context clearly indicates otherwise.

In the interpretation of constituent elements included in the various embodiments of the present disclosure, the constituent elements are interpreted as including an error range even if there is no explicit description thereof. In the description of the various embodiments of the present disclosure, when describing positional relationships, for example, when the positional relationship between two parts is described using “on”, “above”, “below”, “next to”, or the like, one or more other parts may be located between the two parts unless the term “directly” or “closely” is used.

Spatially relative terms such as “below”, “beneath”, “lower”, “above”, and “upper” may be used herein to describe one element's or constituent component's relationship to another element or constituent component as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements would then be oriented “above” the other elements. The exemplary term “below” or “beneath” can, therefore, encompass both an orientation of above and below. Similarly, the exemplary term “above” or “upper” can encompass both an orientation of above and below.

In the description of the various embodiments of the present disclosure, when describing temporal relationships, for example, when the temporal relationship between two actions is described using “after”, “subsequently”, “next”, “before”, or the like, the actions may not occur in succession unless the term “directly” or “just” is used therewith.

It may be understood that, although the terms “first”, “second”, etc. may be used herein to describe various elements, these elements are not to be limited by these terms. These terms are merely used to distinguish one element from another. Therefore, in the present specification, an element indicated by “first” may be the same as an element indicated by “second” without exceeding the technical scope of the present disclosure, unless otherwise mentioned.

The term “at least one” should be understood as including all possible combinations which can be suggested from one or more relevant items. For example, the meaning of “at least one of a first item, a second item, or a third item” may be each one of the first item, the second item, or the third item and also be all possible combinations that can be suggested from two or more of the first item, the second item, and the third item.

The respective features of the various embodiments of the present disclosure may be partially or entirely coupled to and combined with each other, and various technical linkages and modes of operation thereof are possible. These various embodiments may be performed independently of each other, or may be performed in association with each other.

It should be noted that when reference numerals are assigned to the elements of the drawings, the same or similar elements are denoted by the same reference numerals even when they are depicted in different drawings.

In the embodiments of the present disclosure, a source electrode and a drain electrode are distinguished from each other for convenience of explanation. However, the source electrode and the drain electrode may be interchanged. The source electrode may be the drain electrode, and the drain electrode may be the source electrode. Also, the source electrode in any one embodiment may be the drain electrode in another embodiment, and the drain electrode in any one embodiment may be the source electrode in another embodiment.

In one or more embodiments of the present disclosure, for convenience of explanation, a source region is distinguished from a source electrode, and a drain region is distinguished from a drain electrode. However, embodiments of the present disclosure are not limited thereto. For example, a source region may be a source electrode, and a drain region may be a drain electrode. Also, a source region may be a drain electrode, and a drain region may be a source electrode.

The respective features of the various embodiments of the present disclosure may be partially or entirely coupled to and combined with each other, and can be interlocked and operated in various technical ways, as will be fully understood by a person having ordinary skill in the art, and the embodiments can be carried out independently of or in association with each other.

Hereinafter, various embodiments of the present disclosure will be described in detail with reference to the accompanying drawings.

FIG. 1 is a plan view of a display device 100 according to the present disclosure.

A display panel 102 includes a display area AA where an image is displayed and a non-display area NA disposed adjacent to the display area AA where the image is not displayed, which are disposed in a substrate 101. The substrate 101 is formed of a flexible plastic material so as to be bendable. For example, the substrate 101 is formed of polyimide (PI), polyethylene terephthalate (PET), polyethylene naphthalate (PEN), polycarbonate (PC), polyethersulfone (PES), polyacrylate (PAR), polysulfone (PSF), or cyclic-olefin copolymer (COC). However, glass is not excluded as the material of the substrate.

A sub-pixel in the display area AA includes a thin-film transistor that uses an oxide semiconductor material as an active layer.

At least one of a data-driving unit 104 and a gate-driving unit 103 may be disposed in the non-display area NA. In addition, a bending area BA, in which the substrate 101 is bent, may be further included in the non-display area NA.

The gate-driving unit 103 may be directly formed on the substrate 101 using a thin-film transistor that uses a polycrystalline semiconductor material as an active layer. Alternatively, the gate-driving unit 103 may include a thin-film transistor that uses a polycrystalline semiconductor material as an active layer and a thin-film transistor that uses an oxide semiconductor material as an active layer.

The thin-film transistor having an oxide semiconductor layer and the thin-film transistor having a polycrystalline semiconductor layer have high electron mobility in a channel, and are therefore capable of exhibiting high resolution and of being driven with low power.

A plurality of data lines DL and a plurality of gate lines GL may be disposed in the display area AA. For example, the plurality of data lines DL may be disposed in rows or columns, and the plurality of gate lines GL may be disposed in columns or rows. In addition, sub-pixels PX may be disposed in regions defined by the data lines DL and the gate lines GL.

The gate-driving unit 103 including a gate-driving circuit may be disposed in the non-display area NA. The gate-driving circuit of the gate-driving unit 103 sequentially supplies a scan signal to the plurality of gate lines GL, thereby sequentially driving the respective pixel rows in the display area. Here, the gate-driving circuit may also be referred to as a scan-driving circuit. Further, the pixel row refers to a row formed by pixels connected to one gate line.

The gate-driving circuit may be composed of a thin-film transistor having a polycrystalline semiconductor layer, a thin-film transistor having an oxide semiconductor layer, or both a thin-film transistor having a polycrystalline semiconductor layer and a thin-film transistor having an oxide semiconductor layer. In the case in which the same semiconductor material is used in the thin-film transistors disposed in the non-display area NA and the display area AA, the thin-film transistors may be formed simultaneously through the same process.

The gate-driving circuit may include a shift register and a level shifter.

In the display device according to the embodiment of the present disclosure, the gate-driving circuit may be implemented as a gate-in-panel (GIP) type, and may be directly disposed on the substrate 101.

The gate-driving unit 103 including the gate-driving circuit sequentially supplies a scan signal having an on voltage or an off voltage to the plurality of gate lines.

The display device 100 according to the embodiment of the present disclosure may further include a data-driving circuit. When a specific gate line is opened by the gate-driving unit 103 including the gate-driving circuit, the data-driving circuit converts image data into an analog-type data voltage, and supplies the analog-type data voltage to the plurality of data lines DL.

The plurality of gate lines GL disposed on the substrate 101 may include a plurality of scan lines and a plurality of emission control lines. The plurality of scan lines and the plurality of emission control lines are wires that transmit different types of gate signals (scan signals and emission control signals) to gate nodes of different types of transistors (scan transistors and emission control transistors).

The gate-driving unit 103 including the gate-driving circuit may include a scan-driving circuit, which outputs scan signals to a plurality of scan lines, which are gate lines GL of one kind, and an emission-driving circuit, which outputs emission control signals to a plurality of emission control lines, which are gate lines GL of the other kind.

The data lines DL may be disposed so as to pass through the bending area BA. Various data lines DL may be disposed so as to be connected to a data pad.

The bending area BA may be an area in which the substrate 101 is bent. The substrate 101 may be maintained in a flat state in an area other than the bending area BA.

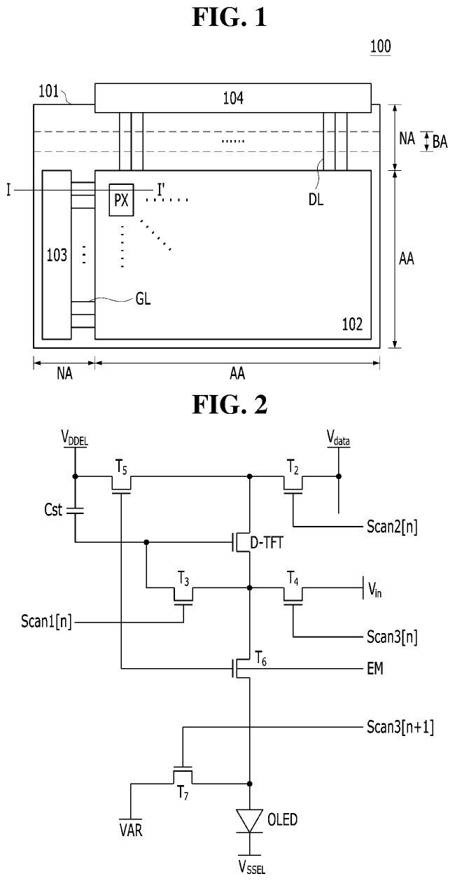

FIG. 2 is a pixel circuit diagram of a sub-pixel according to an embodiment of the present disclosure. A pixel circuit diagram in which seven thin-film transistors D-TFT, T₂ to T₇ and a storage capacitor Cst are provided is given by way of example. One of the seven thin-film transistors may be a driving thin-film transistor, and the remaining ones thereof may be switching thin-film transistors for internal compensation.

The following description of the embodiment of the present disclosure is given on the assumption that a driving thin-film transistor D-TFT uses an oxide semiconductor pattern as an active layer, and a T₃ thin-film transistor, which is located adjacent to the driving thin-film transistor D-TFT, uses an oxide semiconductor pattern as an active layer. Further, at least one of the remaining switching thin-film transistors for internal compensation may use a polycrystalline semiconductor pattern as an active layer. However, the present disclosure is not limited to the example illustrated in FIG. 2, and is also applicable to internal compensation circuits having any of various configurations.

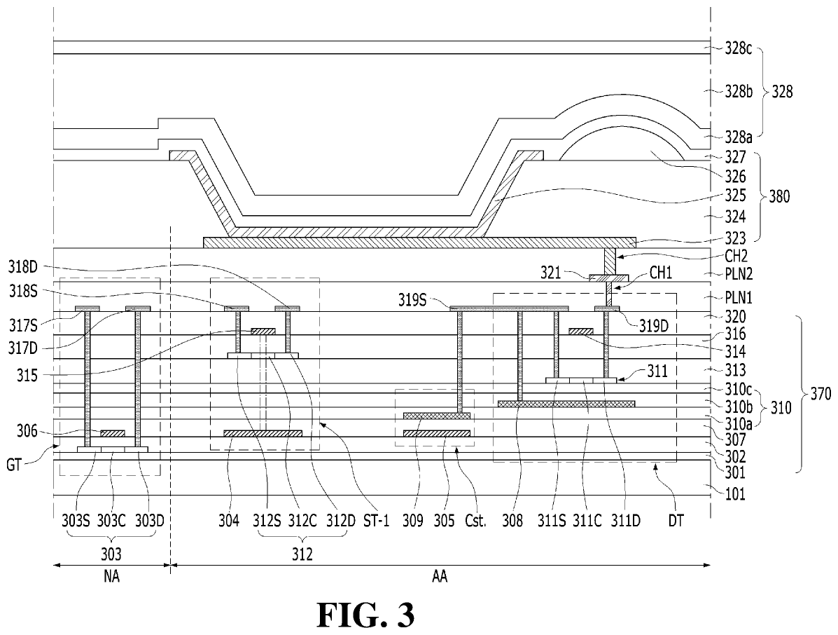

FIG. 3 is a cross-sectional view of configuration that includes a first gate-driving thin-film transistor GT, which is disposed in the non-display area NA, particularly, in the gate-driving unit, and uses a polycrystalline semiconductor pattern as an active layer, and that further includes a single driving thin-film transistor DT, a single switching thin-film transistor ST-1, and a single storage capacitor Cst, which are disposed in the sub-pixel PX.

Described briefly, one sub-pixel PX includes a pixel circuit portion 370, which is disposed on the substrate 101, and a light-emitting element portion 380, which is electrically connected to the pixel circuit portion 370. The pixel circuit portion 370 and the light-emitting element portion 380 are electrically isolated from each other by planarization layers PLN1 and PLN2.

Here, the pixel circuit portion 370 refers to an array portion that includes a driving thin-film transistor DT, a switching thin-film transistor ST-1, and a storage capacitor Cst to drive one sub-pixel PX. Further, the light-emitting element portion 380 refers to an array portion that includes an anode, a cathode, and a light-emitting layer disposed between the anode and the cathode to emit light.

Although the pixel circuit portion 370 is illustrated by way of example in FIG. 3 as including a single driving thin-film transistor DT, a single switching thin-film transistor ST-1, and a single storage capacitor Cst, the present disclosure is not limited thereto.

In particular, in the embodiment of the present disclosure, each of a driving thin-film transistor DT and at least one switching thin-film transistor ST-1 uses an oxide semiconductor pattern as an active layer. A thin-film transistor that uses an oxide semiconductor material as an active layer exhibits an improved leakage-current-blocking effect and incurs relatively low manufacturing costs compared to a thin-film transistor that uses a polycrystalline semiconductor material as an active layer. Therefore, in order to reduce the amount of power that is consumed and manufacturing costs, according to the embodiment of the present disclosure, an oxide semiconductor material is used to manufacture not only a driving thin-film transistor but also at least one switching thin-film transistor.

An oxide semiconductor may be made of an oxide of a metal such as zinc (Zn), indium (In), gallium (Ga), tin (Sn), or titanium (Ti), or a combination of a metal such as zinc (Zn), indium (In), gallium (Ga), tin (Sn), or titanium (Ti) and an oxide thereof. More specifically, an oxide semiconductor may include zinc oxide (ZnO), zinc-tin oxide (ZTO), zinc-indium oxide (ZIO), indium oxide (InO), titanium oxide (TiO), indium-gallium-zinc oxide (IGZO), or indium-zinc-tin oxide (IZTO).

In the pixel circuit portion constituting one sub-pixel, an oxide semiconductor material may be used to form all of the thin-film transistors, or may be used to form at least one switching thin-film transistor.

It is difficult to ensure the reliability of a thin-film transistor that uses an oxide semiconductor material, whereas a thin-film transistor that uses a polycrystalline semiconductor material exhibits a high operational speed and improved reliability. Therefore, the embodiment of the present disclosure illustrated in FIG. 3 will be described on the assumption that an oxide semiconductor material is used to manufacture one of the switching thin-film transistors and the driving thin-film transistor DT, and a polycrystalline semiconductor material is used to manufacture the thin-film transistors constituting the gate-driving unit. However, the present disclosure is not limited to the embodiment illustrated in FIG. 3. That is, an oxide semiconductor material may be used to manufacture all of the thin-film transistors constituting the sub-pixel, or a polycrystalline semiconductor material may be used to manufacture all of the thin-film transistors constituting the gate-driving unit. Alternatively, thin-film transistors that use an oxide semiconductor material and thin-film transistors that use a polycrystalline semiconductor material may be combined to constitute the gate-driving unit.

A substrate 101 may be configured as a multi-layer substrate in which an organic film and an inorganic film are alternately stacked. For example, the substrate 101 may be formed by alternately stacking an organic film such as polyimide and an inorganic film such as silicon oxide (SiO₂).

A lower buffer layer 301 is formed on the substrate 101. The lower buffer layer 301 serves to block or at least reduce entry of moisture or the like from the outside. The lower buffer layer 301 may be formed by stacking silicon oxide (SiO₂) films in multiple layers.

A second buffer layer (not shown) may be further formed on the lower buffer layer 301 in order to more assuredly protect elements disposed in the pixel circuit portion 370 from moisture.

A first thin-film transistor GT is formed on the substrate 101 in the non-display area NA. The first thin-film transistor may use a polycrystalline semiconductor pattern as an active layer. The first thin-film transistor GT includes a first polycrystalline semiconductor pattern 303, which includes a channel through which electrons or holes move, a first gate electrode 306, a first source electrode 317S, and a first drain electrode 317D.

The first polycrystalline semiconductor pattern 303 is formed of a polycrystalline semiconductor material. The first polycrystalline semiconductor pattern 303 includes a first channel region 303C disposed in the middle thereof, and further includes a first source region 303S and a first drain region 303D, which are disposed with the first channel region 303C interposed therebetween.

The first source region 303S and the first drain region 303D are conductive regions obtained by doping an intrinsic polycrystalline semiconductor pattern with a predetermined concentration of group V or group III impurity ions, such as phosphorus (P) or boron (B).

The first channel region 303C maintains the intrinsic state of the polycrystalline semiconductor material, and provides a route along which electrons or holes move.

The first thin-film transistor GT includes a first gate electrode 306, which overlaps the first channel region 303C of the first polycrystalline semiconductor pattern 303. A first gate insulating layer 302 is interposed between the first gate electrode 306 and the first polycrystalline semiconductor pattern 303.

According to an embodiment of the present disclosure, the first thin-film transistor GT is of a top-gate type in which the first gate electrode 306 is located above the first polycrystalline semiconductor pattern 303. Accordingly, a first storage capacitor electrode 305 and a second light-blocking pattern 304, which are formed of a first gate electrode material, may be formed through a single mask process, thus reducing the number of mask processes.

The first gate electrode 306 is made of a metal material. For example, the first gate electrode 306 may take the form of a single layer or multiple layers made of molybdenum (Mo), aluminum (Al), chromium (Cr), gold (Au), titanium (Ti), nickel (Ni), neodymium (Nd), copper (Cu), or an alloy thereof. However, the present disclosure is not limited thereto.

A first interlayer insulating layer 307 is deposited on the first gate electrode 306. The first interlayer insulating layer 307 may be formed of silicon nitride (SiNx). Particularly, the first interlayer insulating layer 307, which is formed of silicon nitride (SiNx), may contain hydrogen particles. When a heat treatment process is performed after forming the first channel region 303 and depositing the first interlayer insulating layer 307 thereon, the hydrogen particles contained in the first interlayer insulating layer 307 permeate the first source region 303S and the first drain region 303D, and thus contribute to improving the conductivity of the polycrystalline semiconductor material and stabilization thereof. This may be called a hydrogenation process.

The first thin-film transistor GT may further include an upper buffer layer 310, a second gate insulating layer 313, a third gate insulating layer 316, and a second interlayer insulating layer 320, which are sequentially formed on the first interlayer insulating layer 307. The first source electrode 317S and the first drain electrode 317D may be formed on the second interlayer insulating layer 320, and may be respectively connected to the first source region 303S and to the first drain region 303D.

The upper buffer layer 310 isolates the first polycrystalline semiconductor pattern 303 from a first oxide semiconductor pattern 311 of the driving thin-film transistor DT, which is formed of an oxide semiconductor material, and a second oxide semiconductor pattern 312 of the first switching thin-film transistor ST-1, which is formed of an oxide semiconductor material. Further, the upper buffer layer 310 provides a base on which the first oxide semiconductor pattern 311 and the second oxide semiconductor pattern 312 are formed.

The second interlayer insulating layer 320 is an interlayer insulating layer that covers a second gate electrode 314 of the driving thin-film transistor DT and a third gate electrode 315 of the first switching thin-film transistor ST-1. Since the second interlayer insulating layer 320 is formed on the first oxide semiconductor pattern 311 and the second oxide semiconductor pattern 312, which are made of an oxide semiconductor material, the second interlayer insulating layer 320 may be configured as an inorganic film that does not contain hydrogen particles.

Each of the first source electrode 317S and the first drain electrode 317D may take the form of a single layer or multiple layers made of molybdenum (Mo), aluminum (Al), chromium (Cr), gold (Au), titanium (Ti), nickel (Ni), neodymium (Nd), copper (Cu), or an alloy thereof. However, the present disclosure is not limited thereto.

The driving thin-film transistor DT is formed on the upper buffer layer 310.

According to an embodiment of the present disclosure, the driving thin-film transistor DT includes the first oxide semiconductor pattern 311.

In a conventional driving thin-film transistor, a polycrystalline semiconductor pattern, which is advantageous from the aspect of high-speed operation, is used as an active layer. However, the conventional driving thin-film transistor, which includes the polycrystalline semiconductor pattern, has a problem in that leakage current is generated in an off state, and thus a large amount of power is consumed. Therefore, the embodiment of the present disclosure proposes a driving thin-film transistor DT that uses an oxide semiconductor pattern, which is advantageous from the aspect of prevention of generation of leakage current, as an active layer.

However, in the case of a thin-film transistor that uses an oxide semiconductor pattern as an active layer, a current fluctuation value with respect to a unit voltage fluctuation value is large due to the characteristics of an oxide semiconductor material, and thus defects frequently occur in a region of low grayscale values, in which precise current control is required. Therefore, the embodiment of the present disclosure provides a driving thin-film transistor in which fluctuation in the value of current in an active layer is relatively insensitive to fluctuation in the value of voltage applied to a gate electrode.

Referring to FIG. 3, the driving thin-film transistor DT includes a first oxide semiconductor pattern 311 formed on the upper buffer layer 310, a second gate insulating layer 313 covering the first oxide semiconductor pattern 311, a third gate insulating layer 316 disposed on the second gate insulating layer 313, a second gate electrode 314 formed on the third gate insulating layer 316 so as to overlap the first oxide semiconductor pattern 311, and a second interlayer insulating layer 320 covering the second gate electrode 314, and further includes a second source electrode 3195 and a second drain electrode 319D, which are disposed on the second interlayer insulating layer 320.

In addition, the driving thin-film transistor DT further includes a first light-blocking pattern 308, which is inserted into the upper buffer layer 310 so as to overlap the first oxide semiconductor pattern 311.

Substantially, the first light-blocking pattern 308 is inserted into the upper buffer layer 310. In the embodiment of the present disclosure, a plurality of sub-upper buffer layers are provided. That is, in the upper buffer layer 310, a first sub-upper buffer layer 310a, a second sub-upper buffer layer 310b, and a third sub-upper buffer layer 310c may be sequentially stacked. The first light-blocking pattern 308 is formed on the first sub-upper buffer layer 310a, which is disposed on the first interlayer insulating layer 307. In addition, the second sub-upper buffer layer 310b completely covers the top of the first light-blocking pattern 308, and the third sub-upper buffer layer 310c is formed on the second sub-upper buffer layer 310b.

The first sub-upper buffer layer 310a and the third sub-upper buffer layer 310c may be formed of silicon oxide (SiO₂).

The first sub-upper buffer layer 310a and the third sub-upper buffer layer 310c are made of silicon oxide (SiO₂), which does not contain hydrogen particles, thereby protecting the oxide semiconductor pattern, the reliability of which may be deteriorated due to permeation of hydrogen particles during a heat treatment process.

The second sub-upper buffer layer 310b may be made of silicon nitride (SiNx), having excellent ability to trap hydrogen particles. The second sub-upper buffer layer 310b may be formed on a portion of the first sub-upper buffer layer 310a so as to cover both the upper surface and the side surface of the first light-blocking pattern 308 to thus completely seal the first light-blocking pattern 308. Alternatively, the second sub-upper buffer layer 310b may be formed on the entire surface of the first sub-upper buffer layer 310a on which the first light-blocking pattern 308 is formed. Silicon nitride (SiNx) has better ability to trap hydrogen particles than silicon oxide (SiO₂). That is, when a hydrogenation process of introducing hydrogen particles into the first polycrystalline semiconductor pattern 303 of the first thin-film transistor GT is performed, the second sub-upper buffer layer 310b, including silicon nitride, traps hydrogen particles generated in the first interlayer insulating layer 307, thereby protecting oxide semiconductor patterns formed thereon from the hydrogen particles. When hydrogen particles permeate the oxide semiconductor pattern, a problem occurs in which oxide semiconductors have different threshold voltages or different channel conductivities depending on the formation positions thereof. In particular, it is important to ensure the reliability of the driving thin-film transistor, since the driving thin-film transistor directly contributes to the operation of the light-emitting element.

Therefore, in the embodiment of the present disclosure, since the second sub-upper buffer layer 310b, which covers the first light-blocking pattern 308, is formed over part or all of the first sub-upper buffer layer 310a, it may be possible to prevent or at least reduce deterioration in the reliability of the driving thin-film transistor DT due to hydrogen particles.

In addition, in the embodiment of the present disclosure, the first light-blocking pattern 308 may be formed as a metal layer including a titanium (Ti) material, which has excellent ability to trap hydrogen particles. For example, the metal layer may be a single layer of titanium, multiple layers of molybdenum (Mo) and titanium (Ti), or an alloy of molybdenum (Mo) and titanium (Ti). However, the present disclosure is not limited thereto, and any other metal layer including titanium (Ti) may be adopted.

Titanium (Ti) traps hydrogen particles diffusing in the upper buffer layer 310 to prevent or at least reduce the hydrogen particles from reaching the first oxide semiconductor pattern 311. Therefore, in the driving thin-film transistor DT according to the embodiment of the present disclosure, the first light-blocking pattern 308 is formed as a layer of metal such as titanium, having the ability to trap hydrogen particles, and is covered with a silicon nitride (SiNx) layer, having the ability to trap hydrogen particles, so that it is possible to alleviate the problem in which the reliability of the oxide semiconductor pattern is deteriorated by hydrogen particles.

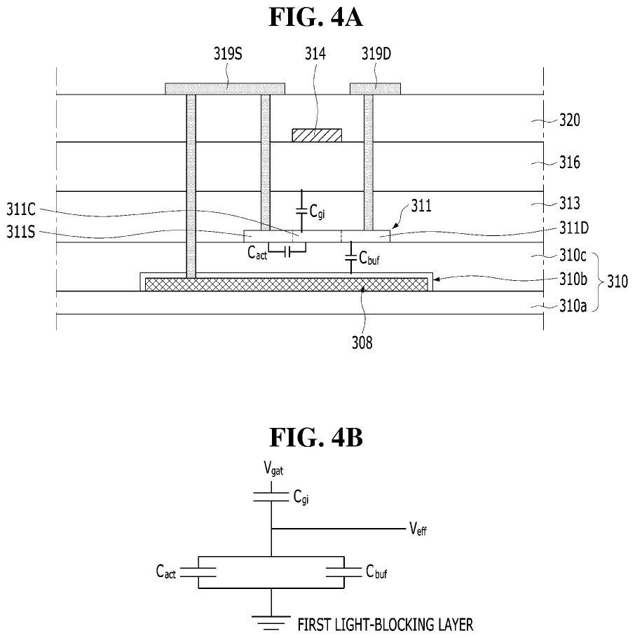

The second sub-upper buffer layer 310b including silicon nitride (SiNx) is not deposited on the entire surface of the display area, unlike the first sub-upper buffer layer 310a, and may be deposited only on a portion of the upper surface of the first sub-upper buffer layer 310a so as to selectively cover only the first light-blocking pattern 308. This configuration is illustrated in FIG. 4A.

The second sub-upper buffer layer 310b is formed of a material different from that of the first sub-upper buffer layer 310a. That is, the second sub-upper buffer layer 310b is formed as a silicon nitride (SiNx) film. Thus, when the second sub-upper buffer layer 310b is deposited on the entire surface of the display area, film lifting may occur. To address this problem, the second sub-upper buffer layer 310b may be selectively formed only on a necessary portion, that is, only at a position where the first light-blocking pattern 308 is formed.

In one embodiment, the first light-blocking pattern 308 and the second sub-upper buffer layer 310b are formed vertically below the first oxide semiconductor pattern 311 so as to overlap the first oxide semiconductor pattern 311, from the aspect of the functionality thereof. Further, the first light-blocking pattern 308 may be formed to be larger than the first oxide semiconductor pattern 310 so as to completely overlap the first oxide semiconductor pattern 310.

Meanwhile, the second source electrode 319S of the driving thin-film transistor DT may be electrically connected to the first light-blocking pattern 308.

As described above, when the first light-blocking pattern 308 is inserted into the upper buffer layer 310 and the second source electrode 319S is electrically connected to the first light-blocking pattern 308, the following additional effect may be obtained.

This will be described with reference to FIGS. 4A and 4B.

FIG. 4A is a cross-sectional view of the driving thin-film transistor, among the components shown in FIG. 3 according to one embodiment. FIG. 4B is a circuit diagram showing the relationship between the parasitic capacitance generated in the driving thin-film transistor and voltage applied thereto according to one embodiment.

Referring to FIG. 4A, since the second source region 311S and the second drain region 311D are doped with impurities, a parasitic capacitance C_{act} is generated inside the first oxide semiconductor pattern 311, a parasitic capacitance C_{gi} is generated between the second gate electrode 314 and the first oxide semiconductor pattern 311, and a parasitic capacitance C_{buf} is generated between the first light-blocking pattern 308, which is electrically connected to the second source electrode 319S, and the first oxide semiconductor pattern 311.

The first oxide semiconductor pattern 311 and the first light-blocking pattern 308 are electrically connected to each other via the second source electrode 319S, and thus the parasitic capacitance C_{act} and the parasitic capacitance C_{buf} are connected in parallel to each other, and the parasitic capacitance C_{act} and the parasitic capacitance C_{gi} are connected in series to each other. In addition, when a gate voltage of V_{gat} is applied to the second gate electrode 314, the effective voltage V_{eff} that is actually applied to the first oxide semiconductor pattern 311 satisfies the following Equation 1, wherein Δ indicates variation of the corresponding voltage V_{eff} or V_{gat}.

ΔV_{eff}=C_{gi}/(C_{gi}+C_{act}+C_{buf})×ΔV_{gat} [Equation 1]

Accordingly, the effective voltage applied to the channel of the first oxide semiconductor pattern 311 is inversely proportional to the parasitic capacitance C_{buf}, and thus the effective voltage applied to the first oxide semiconductor pattern 311 may be adjusted by adjusting the parasitic capacitance C_{buf}.

That is, when the first light-blocking pattern 308 is disposed close to the first oxide semiconductor pattern 311 to increase the parasitic capacitance C_{buf}, the actual value of the current flowing through the first oxide semiconductor pattern 311 may be reduced.

The reduction in the effective value of the current flowing through the first oxide semiconductor pattern 311 means that the range within which it is possible to control the driving thin-film transistor DT using the voltage V_{gat} that is actually applied to the second gate electrode 314 is widened.

Therefore, in the embodiment of the present disclosure illustrated in FIG. 3, the first light-blocking pattern 308 is disposed relatively close to the first oxide semiconductor pattern 311, thereby widening the range of grayscale values within which the driving thin-film transistor DT is capable of performing control. As a result, the light-emitting element may be precisely controlled even at low grayscale values, and thus it may be possible to solve a problem of non-uniform luminance, which frequently occurs at low grayscale values. Thus, in the embodiment of the present disclosure, the parasitic capacitance C_{buf} may be significantly increased compared to the parasitic capacitance C_{gi}, such that the control range of the driving thin-film transistor DT may be improved in low grayscale values, and s-factor value of the driving thin-film transistor DT may be increased. For example, in the embodiment of the present disclosure, the parasitic capacitance C_{buf} may be larger than the parasitic capacitance C_{gi}.

The first switching thin-film transistor ST-1 includes a second oxide semiconductor pattern 312 formed on the second gate insulating layer 313, a third gate insulating layer 316 covering the second oxide semiconductor pattern 312, a third gate electrode 315 formed on the third gate insulating layer 316, and a second interlayer insulating layer 320 covering the third gate electrode 315, and further includes a third source electrode 318S and a third drain electrode 318D, which are formed on the second interlayer insulating layer 320.

The first switching thin-film transistor ST-1 may further include a second light-blocking pattern 304, which is disposed below the second oxide semiconductor pattern 312 so as to overlap the same. Particularly, the second light-blocking pattern 304 may be made of the same material as the first gate electrode 306, and may be formed on the upper surface of the first gate insulating layer 302. The second light-blocking pattern 304 may not be an essential component. That is, in some cases, the second light-blocking pattern 304 may be omitted from the first switching thin-film transistor ST-1.

Alternatively, the second light-blocking pattern 304 may be formed on the same layer and of the same material as a second storage capacitor electrode 309, rather than being formed on the same layer and of the same material as the first gate electrode 306. That is, when one sub-pixel SPX is provided with a plurality of switching thin-film transistors, the plurality of switching thin-film transistors may be respectively provided with second light-blocking patterns 304 in different layers, thus increasing design freedom.

Although the second light-blocking pattern 304 is illustrated in FIG. 3 as not being electrically connected to the third gate electrode 315, the second light-blocking pattern 304 may be electrically connected to the third gate electrode 315 to form a dual gate. Since the first switching thin-film transistor ST-1 has a dual-gate structure, it may be possible to more precisely control the flow of current flowing through the third channel region 312C, to reduce the overall size of the display device, and to realize a high-definition display device.

The second oxide semiconductor pattern 312 is made of an oxide semiconductor material, and includes a third channel region 312C, which maintains the intrinsic state of the oxide semiconductor material rather than being doped with impurities, and a third source region 312S and a third drain region 312D, which are doped with impurities so as to be conductive.

Similar to the first source electrode 317S and the first drain electrode 317D, each of the third source electrode 318S and the third drain electrode 318D may take the form of a single layer or multiple layers made of molybdenum (Mo), aluminum (Al), chromium (Cr), gold (Au), titanium (Ti), nickel (Ni), neodymium (Nd), copper (Cu), or an alloy thereof.

The third source electrode 318S and the third drain electrode 318D are formed on the second interlayer insulating layer 320 simultaneously with and of the same material as the first source electrode 317S and the first drain electrode 317D, thus making it possible to reduce the number of mask processes.

Meanwhile, referring to FIG. 3, the pixel circuit portion 370 according to the embodiment of the present disclosure further includes the storage capacitor Cst.

The storage capacitor Cst stores a data voltage applied thereto through the data lines for a designated period of time, and then provides the data voltage to the light-emitting element.

The storage capacitor Cst includes two electrodes corresponding to each other and a dielectric disposed therebetween. The storage capacitor Cst includes a first storage capacitor electrode 305, which is made of the same material as and is disposed on the same layer as the first gate electrode 306, and a second storage capacitor electrode 309, which is made of the same material as and is disposed on the same layer as the first light-blocking pattern 308.

The first interlayer insulating layer 307 is located between the first storage capacitor electrode 305 and the second storage capacitor electrode 309.

The second storage capacitor electrode 309 of the storage capacitor Cst may be electrically connected to the second source electrode 319S.

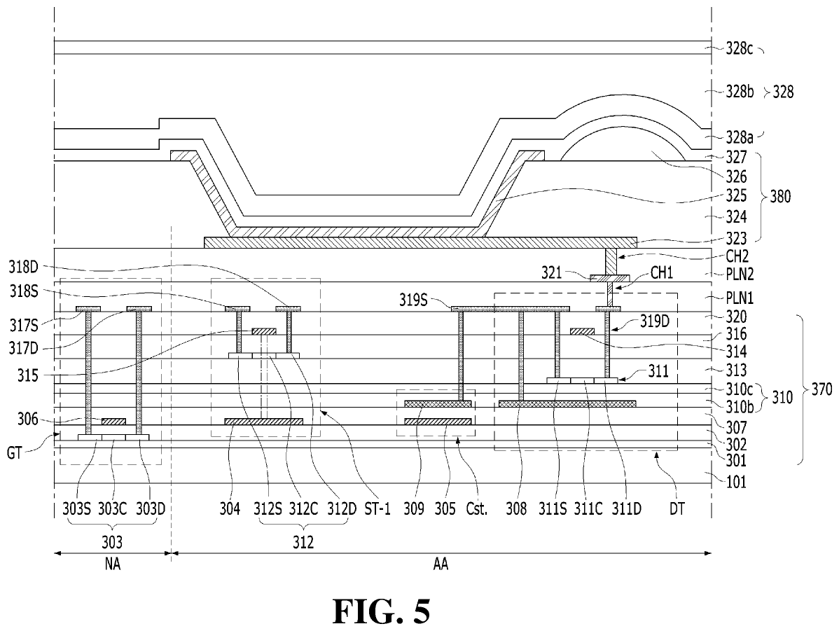

Next, an organic light-emitting display device according to a second embodiment of the present disclosure will be described with reference to FIG. 5. The organic light-emitting display device according to the second embodiment is substantially the same as the organic light-emitting display device according to the first embodiment. However, in the second embodiment, the first light-blocking pattern 308 may be disposed on the same layer as the second storage capacitor electrode 309, and thus the second storage capacitor electrode 309 and the first light-blocking pattern 308 may be formed using a single mask.

The upper buffer layer 310 may be composed of the second sub-upper buffer layer 310b and the third sub-upper buffer layer 310c, which are used in the first embodiment. The first light-blocking pattern 308 may be disposed on the first interlayer insulating layer 307.

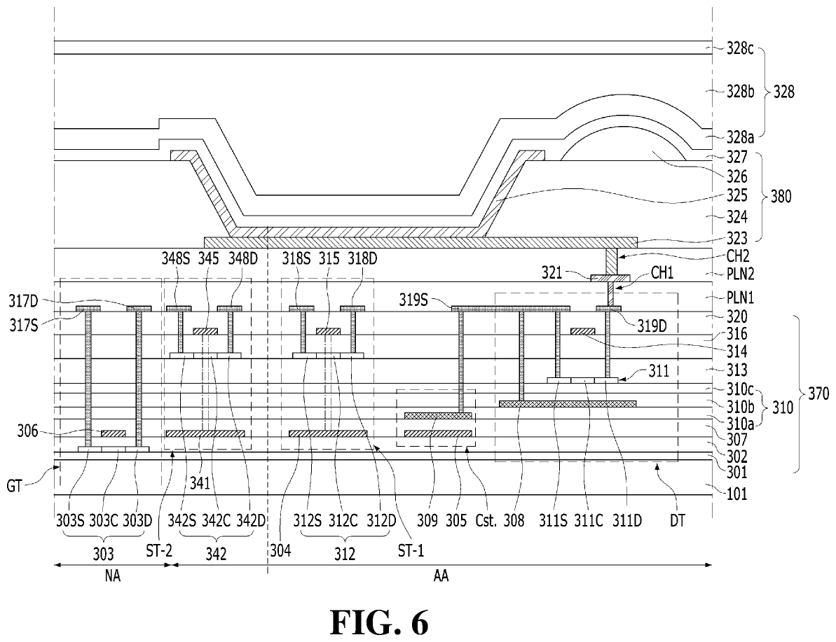

Next, the third embodiment of the present disclosure will be described with reference to FIG. 6. In the third embodiment, which is a modification of the first embodiment, a second switching thin-film transistor ST-2, which includes a third oxide semiconductor pattern 342, may be disposed in the non-display area.

That is, the gate-driving unit may form a circuit by combining the first thin-film transistor GT, which includes the polycrystalline semiconductor pattern, and the second switching thin-film transistor ST-2. In some cases, a pair including the polycrystalline semiconductor and the oxide semiconductor may form a CMOX.

A “CMOX” is similar to a CMOS, which is provided with an n-type thin-film transistor and a p-type thin-film transistor in a pair, with the exception that one of the thin-film transistors is substituted with an oxide semiconductor.

The information and structure of layers constituting the second switching thin-film transistor ST-2 may be the same as for the first switching thin-film transistor ST-1.

That is, the second switching thin-film transistor ST-2 includes a third oxide semiconductor pattern 342 formed on the second gate insulating layer 313, a third gate insulating layer 316 covering the third oxide semiconductor pattern 342, a fourth gate electrode 345 formed on the third gate insulating layer 316, and a second interlayer insulating layer 320 covering the fourth gate electrode 345, and further includes a fourth source electrode 348S and a fourth drain electrode 348D, which are formed on the second interlayer insulating layer 320.

The second switching thin-film transistor ST-2 may further include a third light-blocking pattern 341, which is disposed below the third oxide semiconductor pattern 342 so as to overlap the same. Particularly, the third light-blocking pattern 341 may be made of the same material as the first gate electrode 306, and may be formed on the upper surface of the first gate insulating layer 302. The third light-blocking pattern 341 may not be an essential component. That is, in some cases, the third light-blocking pattern 341 may be omitted from the second switching thin-film transistor ST-2.

Although the third light-blocking pattern 341 is illustrated in FIG. 6 as not being electrically connected to the fourth gate electrode 345, the third light-blocking pattern 341 may be electrically connected to the fourth gate electrode 345 to form a dual gate. Since the second switching thin-film transistor ST-2 has a dual-gate structure, it may be possible to more precisely control the flow of current flowing through the fourth channel region 342C, to reduce the overall size of the display device, and to realize a high-definition display device.

The third oxide semiconductor pattern 342 is made of an oxide semiconductor material, and includes a fourth channel region 342C, which maintains the intrinsic state of the oxide semiconductor material rather than being doped with impurities, and a fourth source region 342S and a fourth drain region 342D, which are doped with impurities so as to be conductive.

Similar to the first source electrode 317S and the first drain electrode 317D, each of the fourth source electrode 348S and the fourth drain electrode 348D may take the form of a single layer or multiple layers made of molybdenum (Mo), aluminum (Al), chromium (Cr), gold (Au), titanium (Ti), nickel (Ni), neodymium (Nd), copper (Cu), or an alloy thereof.

The fourth source electrode 348S and the fourth drain electrode 348D are formed on the second interlayer insulating layer 320 simultaneously with and of the same material as the first source electrode 317S and the first drain electrode 317D, thus making it possible to reduce the number of mask processes.

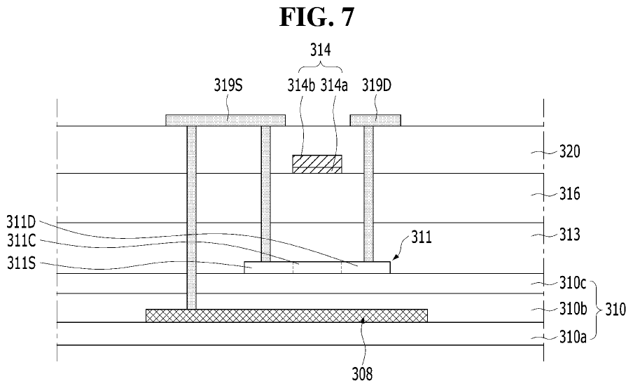

Meanwhile, referring to FIG. 7, in a fourth embodiment of the present disclosure, the second gate electrode 314 may take the form of multiple layers including titanium (Ti).

That is, referring to FIG. 5, the second gate electrode 314 may include multiple layers, which include a second lower gate electrode 314a including titanium (Ti) and a second upper gate electrode 314b formed of a metal other than titanium, for example, molybdenum (Mo).

When the second gate electrode 314 includes multiple metal layers including titanium, the metal layer including titanium blocks hydrogen particles that may move downwards from above the driving thin-film transistor DT, thereby protecting the first oxide semiconductor pattern 311.

The configuration of the pixel circuit portion 370 constituting the unit pixel according to the present disclosure has been described above. Since the pixel circuit portion 370 according to the embodiment of the present disclosure includes a plurality of thin-film transistors including different types of semiconductor materials, a large number of layers may be formed, and a large number of masks may be used. Therefore, in order to minimize the number of masks that are used, the embodiment of the present disclosure is configured such that a plurality of layers is simultaneously formed.

That is, the first gate electrode 306 constituting the first thin-film transistor GT, the second light-blocking pattern 304 constituting the first switching thin-film transistor ST-1, and the first storage capacitor electrode 305 constituting the storage capacitor Cst may be formed of the same material as and on the same layer as each other. Further, the second storage capacitor electrode 309 constituting the storage capacitor Cst and the first light-blocking pattern 308 constituting the driving thin-film transistor DT may be formed of the same material as and on the same layer as each other. Further, the second gate electrode 314 constituting the driving thin-film transistor DT and the third gate electrode 315 constituting the first switching thin-film transistor ST-1 may be formed of the same material as and on the same layer as each other.

Further, the first source electrode 317S and the first drain electrode 317D constituting the first thin-film transistor GT, the second source electrode 319S and the second drain electrode 319D constituting the driving thin-film transistor DT, and the third source electrode 318S and the third drain electrode 318D constituting the first switching thin-film transistor ST-1 may be formed of the same material as and on the same layer as each other.

Meanwhile, the gate electrodes 314 and 315 of the driving thin-film transistor DT and the first switching thin-film transistor ST-1 may act as a mask when the first oxide semiconductor pattern 311 and the second oxide semiconductor pattern 312 are doped with impurities. In this case, the distance between the first oxide semiconductor pattern 311 and the second gate electrode 314 and the distance between the second oxide semiconductor pattern 312 and the third gate electrode 315 are different from each other, and thus when doped under the same conditions, the first oxide semiconductor pattern 311 and the second oxide semiconductor pattern 312 are doped at different doses. That is, the first oxide semiconductor pattern 311 constituting the driving thin-film transistor DT is doped with a smaller amounts of impurities, thus helping increase the s-factor value of the driving thin-film transistor DT.

In addition, referring to FIG. 3, a first planarization layer PLN1 and a second planarization layer PLN2 may be sequentially formed on the pixel circuit portion 370 in order to planarize the upper end of the pixel circuit portion 370. The light-emitting element portion 380 includes a first electrode 323, which is an anode, a second electrode 327, which is a cathode corresponding to the first electrode 323, and a light-emitting layer 325, which is interposed between the first electrode 323 and the second electrode 327. The first electrode 323 is formed in each sub-pixel.

The light-emitting element portion 380 is connected to the pixel circuit portion 370 via a connection electrode 321, which is formed on the first planarization layer PLN1. Particularly, the first electrode 323 of the light-emitting element portion 380 and the second drain electrode 319D of the driving thin-film transistor DT constituting the pixel circuit portion 370 are connected to each other via the connection electrode 321.

The first electrode 323 is connected to the connection electrode 321, which is exposed through a contact hole CH2 formed through the second planarization layer PLN2. Further, the connection electrode 321 is connected to the second drain electrode 319D, which is exposed through a contact hole CH1 formed through the first planarization layer PLN1.

The first electrode 323 may be formed in a multi-layer structure including a transparent conductive film and an opaque conductive film having high reflection efficiency. The transparent conductive film may be formed of a material having a relatively high work function, e.g., indium-tin-oxide (ITO) or indium-zinc-oxide (IZO), and the opaque conductive film may be formed in a single-layer or multi-layer structure including Al, Ag, Cu, Pb, Mo, Ti, or an alloy thereof. For example, the first electrode 323 may be formed in a structure such that a transparent conductive film, an opaque conductive film, and a transparent conductive film are sequentially stacked, or such that a transparent conductive film and an opaque conductive film are sequentially stacked.

The light-emitting layer 325 is formed by stacking, on the first electrode 323, a hole-related layer, an organic light-emitting layer, and an electron-related layer, either in that order or in the reverse order.

A bank layer 324 is a pixel-defining film that exposes the first electrode 323 of each sub-pixel. The bank layer 324 may be formed of an opaque material (e.g., black) in order to prevent optical interference between neighboring sub-pixels. In this case, the bank layer 324 includes a light-blocking material including at least one of a color pigment, organic black, or carbon. A spacer 326 may be further disposed on the bank layer 324.

The second electrode 327, which is the cathode, is formed on the upper surface and the side surfaces of the light-emitting layer 325 so as to face the first electrode 323, with the light-emitting layer 325 interposed therebetween. The second electrode 327 may be integrally formed on the entire surface of the active area. In the case in which the second electrode 327 is applied to a top-emission-type organic light-emitting display device, the second electrode 327 may be formed as a transparent conductive film formed of, for example, indium-tin-oxide (ITO) or indium-zinc-oxide (IZO).

An encapsulation portion 328 for preventing or at least reducing the permeation of moisture may be further disposed on the second electrode 327.

The encapsulation portion 328 may include a first inorganic encapsulation layer 328a, a second organic encapsulation layer 328b, and a third inorganic encapsulation layer 328c, which are sequentially stacked.

The first inorganic encapsulation layer 328a and the third inorganic encapsulation layer 328c may be formed of an inorganic material such as silicon oxide (SiOx). The second organic encapsulation layer 328b may be formed of an organic material such as acrylic resin, epoxy resin, phenolic resin, polyamide resin, or polyimide resin.

As is apparent from the above description, an organic light-emitting display device according to the present disclosure includes a driving thin-film transistor and a switching thin-film transistor, which include oxide semiconductor patterns, thereby reducing the amount of leakage current in an off state, thus reducing power consumption. In addition, since a driving thin-film transistor includes an oxide semiconductor pattern, it may be possible to reduce the intensity of the effective voltage that is applied to the oxide semiconductor pattern by adjusting parasitic capacitance and thus to realize precise grayscale expression, thus preventing or minimizing defects such as non-uniform luminance at low grayscale values.

In addition, a light-blocking layer, which is disposed below a driving thin-film transistor, is surrounded by or covered with a silicon nitride material, thereby preventing deterioration in the reliability of an oxide semiconductor pattern due to permeation of hydrogen particles, generated during processing, thereinto.

In addition, a plurality of metal patterns and a plurality of semiconductor patterns are disposed so as to be formed using a single mask, thereby enabling simplification of a process.

In addition, the organic light-emitting display device includes a first light-blocking pattern for blocking permeation of light into a driving thin-film transistor constituting a sub-pixel in order to increase an s-factor value of the driving thin-film transistor. The first light-blocking pattern is disposed close to an active layer of the driving thin-film transistor to increase the s-factor value of the driving thin-film transistor.

It will be appreciated that the technical spirit of the present disclosure has been described herein only for purposes of illustration through the above description and the accompanying drawings, and that combination, separation, substitution, and modifications of components may be made by those skilled in the art without departing from the scope and spirit of the present disclosure. Therefore, the exemplary embodiments of the present disclosure are provided for illustrative purposes only and are not intended to limit the technical spirit of the present disclosure. The scope of the technical spirit of the present disclosure is not limited thereto. The protection scope of the present disclosure should be interpreted based on the appended claims, and it should be appreciated that all technical spirits falling within a range equivalent to the claims are included in the protection scope of the present disclosure.

What is claimed is:

1. An organic light-emitting display device comprising:
a substrate comprising a first area and a second area;
a driving thin-film transistor in the second area, the driving thin-film transistor comprising a first oxide semiconductor pattern; and
at least one switching thin-film transistor in the second area, the switching thin-film transistor comprising a first switching thin-film transistor that includes a second oxide semiconductor pattern,
wherein the driving thin-film transistor comprises a first light-blocking pattern below the first oxide semiconductor pattern such that the first light-blocking pattern overlaps the first oxide semiconductor pattern, and
wherein a vertical distance between the first light-blocking pattern and the first oxide semiconductor pattern is less than a vertical distance between the first light-blocking pattern and the second oxide semiconductor pattern.

2. The organic light-emitting display device according to claim 1, further comprising:
an inorganic film between the first light-blocking pattern and the first oxide semiconductor pattern, the inorganic film comprising silicon nitride.

3. The organic light-emitting display device according to claim 2, wherein the inorganic film has a shape of an island surrounding the first light-blocking pattern.

4. The organic light-emitting display device according to claim 2, wherein the inorganic film is on an entire surface of the substrate such that the inorganic film covers the first light-blocking pattern.

5. The organic light-emitting display device according to claim 1, further comprising:
at least one insulating layer between the first light-blocking pattern and the first oxide semiconductor pattern; and
insulating layers between the first light-blocking pattern and the second oxide semiconductor pattern,
wherein a number of the insulating layers between the first light-blocking pattern and the second oxide semiconductor pattern is greater than a number of the at least one insulating layer between the first light-blocking pattern and the first oxide semiconductor pattern.

6. The organic light-emitting display device according to claim 1, wherein the first oxide semiconductor pattern and the second oxide semiconductor pattern are on different layers.

7. The organic light-emitting display device according to claim 1, further comprising:
a lower buffer layer on the substrate; and
an upper buffer layer between the lower buffer layer and the first oxide semiconductor pattern,
wherein the driving thin-film transistor comprises:
a second gate electrode overlapping the first oxide semiconductor pattern disposed on the upper buffer layer, with a second gate insulating layer and a third gate insulating layer interposed therebetween; and
a second source electrode and a second drain electrode on the second gate electrode and connected to the first oxide semiconductor pattern, and
wherein the first switching thin-film transistor comprises:
a third gate electrode overlapping the second oxide semiconductor pattern disposed on the second gate insulating layer, with the third gate insulating layer interposed therebetween; and
a third source electrode and a third drain electrode disposed on the third gate electrode and connected to the second oxide semiconductor pattern.

8. The organic light-emitting display device according to claim 7, further comprising:
a second light-blocking pattern below the second oxide semiconductor pattern.

9. The organic light-emitting display device according to claim 7, wherein the first light-blocking pattern is connected to the second source electrode.

10. The organic light-emitting display device according to claim 8, wherein the second light-blocking pattern is connected to the third gate electrode.

11. The organic light-emitting display device according to claim 1, wherein the substrate comprises a display area and a non-display area disposed adjacent to the display area,
wherein the first area is disposed in at least one of the non-display area and the display area,
wherein the second area is disposed in the display area, and
wherein the organic light-emitting display device further comprises:
a first thin-film transistor disposed in the first area, the first thin-film transistor comprising a first polycrystalline semiconductor pattern.

12. The organic light-emitting display device according to claim 11, further comprising:
a second switching thin-film transistor disposed in the non-display area, the second switching thin-film transistor comprising a third oxide semiconductor pattern.

13. The organic light-emitting display device according to claim 9, wherein a first parasitic capacitance generated in the first oxide semiconductor pattern is connected in parallel to a second parasitic capacitance generated between the first oxide semiconductor pattern and the first light-blocking pattern, and is connected in series to a third parasitic capacitance generated between the second gate electrode and the first oxide semiconductor pattern.

14. The organic light-emitting display device according to claim 13, wherein the second parasitic capacitance generated between the first oxide semiconductor pattern and the first light-blocking pattern is greater than the third parasitic capacitance generated between the second gate electrode and the first oxide semiconductor pattern.

15. The organic light-emitting display device according to claim 7, wherein each of the second gate electrode and the third gate electrode comprises a plurality of conductive layers, and
wherein at least one of the plurality of conductive layers is a metal layer comprising titanium.

16. The organic light-emitting display device according to claim 8, further comprising:
a storage capacitor comprising a first storage capacitor electrode on a same layer as the second light-blocking pattern, and a second storage capacitor electrode facing the first storage capacitor electrode, with a first interlayer insulating layer interposed therebetween.

17. The organic light-emitting display device according to claim 16, wherein the second storage capacitor electrode is on a same layer as the first light-blocking pattern.

18. The organic light-emitting display device according to claim 7, wherein ions in the first oxide semiconductor pattern are less than ions in the second oxide semiconductor pattern.
